(19) United States
(12) Patent Application Publication
(10) Pub. No.: US 2015/0263163 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventors: Rieko AKIMOTO, Kamakura Kanagawa (JP); Yasushi FUKAI, Kamakura Kanagawa (JP)

(21) Appl. No.: 14/474,006

(22) Filed: Aug. 29, 2014

(30) Foreign Application Priority Data
Mar. 14, 2014 (JP) 2014-051496

(51) Int. Cl. H01L 29/78; H01L 29/08; H01L 29/10

(52) U.S. Cl. CPC H01L 29/7816; H01L 29/1095; H01L 29/0878

(57) ABSTRACT

A semiconductor device includes first and second semiconductor layers, first and second semiconductor regions, a source region, a drain region, and a gate electrode. The second semiconductor layer of a first conductive type is formed over the first semiconductor layer. The first semiconductor region of a second conductive type is formed on a surface of the second semiconductor layer. The source region of the first type is formed on a surface of the first semiconductor region. The drain region of the first type is formed on a surface of the first semiconductor layer having the first type, is separated from the source region. The second semiconductor region of the second type is provided between the drain region and the first semiconductor layer. The gate electrode is formed over the second semiconductor layer and is provided between the drain region and the source region.

### CROSS-REFERENCE TO RELATED APPLICATION

This application is based upon and claims the benefit of priority from Japanese Patent Application No. 2014-051496, filed Mar. 14, 2014, the entire contents of which are incorporated herein by reference.

### FIELD

Embodiments described herein relate to a semiconductor device.

### BACKGROUND

As a Metal Oxide Semiconductor (MOS) transistor having a high breakdown voltage, there has been known a semiconductor device such as a Double Diffused MOS (DMOS) transistor where a channel region of the MOS transistor is formed by a double diffusion process. However, further enhancement of the breakdown voltage with respect to such a semiconductor device is desirable.

### DESCRIPTION OF THE DRAWINGS

FIG. 1 is a schematic cross-sectional view illustrating a semiconductor device according to a first embodiment.

FIG. 2 is a schematic perspective view illustrating the semiconductor device according to the first embodiment.

FIG. 3 is a schematic perspective view illustrating the semiconductor device according to the first embodiment.

FIG. 4 is a schematic cross-sectional view illustrating a semiconductor device according to a second embodiment.

FIG. 5 is a graph illustrating a characteristic of the semiconductor device.

### DETAILED DESCRIPTION

In general, according to one embodiment, there is provided a semiconductor device which includes: a first semiconductor layer; a second semiconductor layer; a first semiconductor region; a source region; a drain region; a second semiconductor region; and a gate electrode. A conductive type of the first semiconductor layer is a first conductive type. The second semiconductor layer is formed over the first semiconductor layer, has a lower dopant concentration than the first semiconductor layer, and is of the first conductive type. The first semiconductor region is formed on a surface of the second semiconductor layer, and is of a second conductive type. The source region is formed on a surface of the first semiconductor region, and is of the first conductive type. The drain region is formed on a surface of the first semiconductor layer, is separated from the source region, and is of the first conductive type. The second semiconductor region is provided between the drain region and the first semiconductor layer, and is of the second conductive type. The gate electrode is formed over the second semiconductor layer and is provided between the drain region and the source region.

Hereinafter, embodiments are explained by reference to drawings.

The drawings are schematic or conceptual views and hence, the relationship between thicknesses and widths of respective components, a ratio of sizes of the respective components and the like are not always equal to those of an actual semiconductor device. Further, even when the identical components are described in the drawings, sizes or ratios of sizes of the components may differ depending on drawings.

In this disclosure and respective drawings, identical elements illustrated in the other drawings are given the same symbols, and the detailed explanation of the identical components is omitted and only different components are explained when appropriate.

### FIRST EMBODIMENT

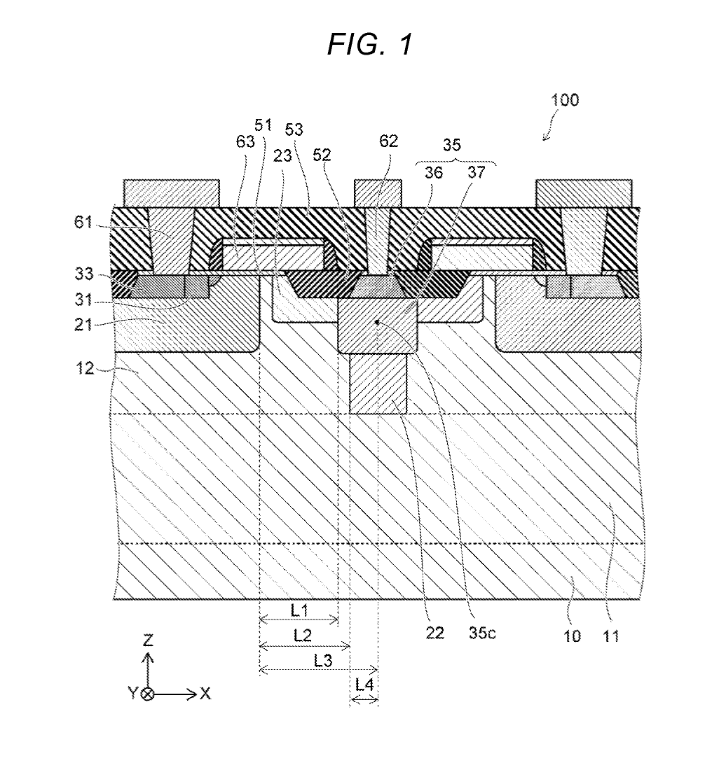

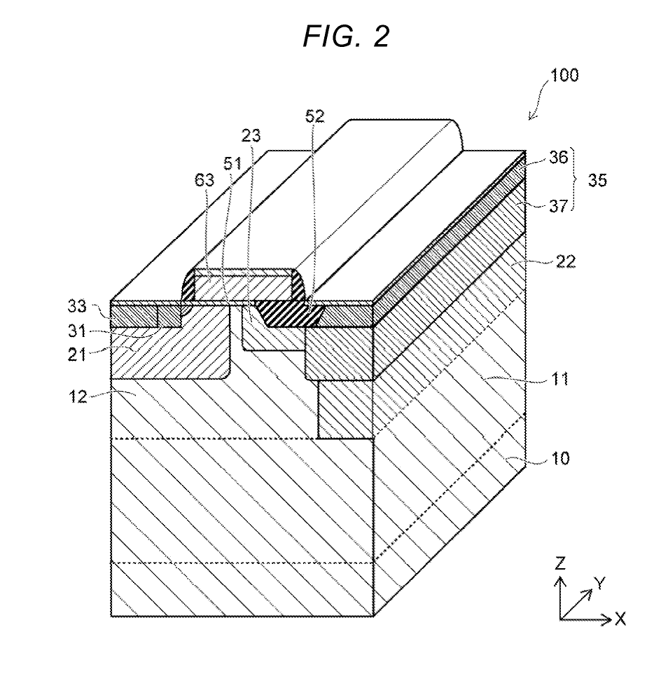

FIG. 1 and FIG. 2 are schematic views which exemplify a semiconductor device according to the first embodiment.

FIG. 1 is a schematic cross-sectional view of the semiconductor device 100 according to the embodiment. FIG. 2 is a schematic perspective view of the semiconductor device 100 according to the embodiment.

As illustrated in FIG. 1 and FIG. 2, the semiconductor device 100 according to the embodiment includes: a first semiconductor layer 11; second semiconductor layers 12; first semiconductor regions 21; a second semiconductor region 22; source regions 31; and a drain region 35.

In this embodiment, the semiconductor device 100 further includes: a substrate 10; third semiconductor regions 23; source electrodes 61; a drain electrode 62; gate electrodes 63; gate insulation films 51; insulating separation films 52 (insulation films); and interlayer insulation layers 53. The semiconductor device 100 is a Double Diffused MOS (DMOS), for example.

For example, silicon (Si) is used for forming the first semiconductor layer 11, the second semiconductor layers 12, the first semiconductor regions 21, the second semiconductor region 22, the source regions 31, the drain region 35 and the like which are explained hereinafter. In the embodiment, silicon carbide or the like may be used as a semiconductor, for example.

A silicon substrate is used as the substrate 10, for example. In this embodiment, p type (second conductive type) silicon is used for forming the substrate 10. N type (first conductive type) silicon may be used for forming the substrate.

In the embodiment explained hereinafter, the explanation is made with respect to the semiconductor device 100 having the n type DMOS structure assuming that a first conductive type is an n type, and a second conductive type is a p type. The explanation made hereinafter is also applicable to a case where a first conductive type is assumed as a p type, and a second conductive type is assumed as an n type.

The first semiconductor layer 11 is formed on the substrate 10. A conductive type of the first semiconductor layer 11 is an n type. The first semiconductor layer 11 forms an n type buried layer.

The second semiconductor layers 12 are formed on the first semiconductor layer 11. A conductive type of the second semiconductor layer 12 is an n type. The second semiconductor layer 12 is formed of an n type epitaxial layer, for example. The source regions 31 and the drain region 35 are formed on the epitaxial layer.

The concentration of an n type dopant in the first semiconductor layer 11 is higher than a concentration of an n type dopant in the second semiconductor layer 12. Phosphorus (P) or arsenic (As) maybe used as an n type dopant, for example.

The first semiconductor regions 21 are formed on the second semiconductor layer 12. A conductive type of the first semiconductor region 21 is a p type. Boron (B) is used as a p type dopant, for example.

The source region 31 (first source region) is formed on a portion of the first semiconductor region 21 with conductive type of the source region 31 being n type. The source region is formed on a front surface portion of the second semiconductor layer 12and the first semiconductor region 21 is brought into contact with a lower surface (a surface which faces the first semiconductor layer 11 in an opposed manner) of the source region 31 and a side surface (a surface which intersects with the second direction) of the source region 31.

The direction (first direction) which extends to the second semiconductor layer 12 from the first semiconductor layer 11 is set as the Z axis direction. One direction orthogonal to the Z axis direction is set as the X axis direction (second direction), that is, the gate length direction of a gate electrode. The direction which is orthogonal to the X axis direction and is also orthogonal to the Z axis direction is set as the Y axis direction, that is, the gate width direction of the gate electrode.

The source electrode 61 is formed on the source region 31. The source electrode 61 is electrically connected with the source region 31. For example, the source electrode 61 is brought into Ohmic contact with the source region 31.

The drain region 35 is formed above the first semiconductor layer 11. A conductive type of the drain region 35 is an n type. The drain region 35 is separated from the source region 31 and the first semiconductor region 21 in the second direction (the X axis direction in this embodiment). In one embodiment, the drain region 35 is formed on the front surface portion of the second semiconductor layer 12.

In this embodiment, the semiconductor device 100 also includes source regions 33 (second source regions). Each second source region 33 is formed on the first semiconductor region 21. The second source region 33 is arranged parallel to the source region 31 in the second direction (X axis direction, for example). For example, the source region 31 is arranged between the second source region 33 and the drain region 35.

In this embodiment, the drain region 35 includes a first drain region 36 and a second drain region 37. The second drain region 37 is provided between the first drain region 36 and the first semiconductor layer 11.

The concentration of an n type dopant in the source region 31 is higher than the concentration of an n type dopant in the second semiconductor layer 12. The concentration of an n type dopant in the drain region 35 is higher than the concentration of an n type dopant in the second semiconductor layer 12.

The concentration of an n type dopant in the first drain region 36 is higher than a concentration of an n type dopant in the second drain region 37. For example, the concentration of an n type dopant in the first semiconductor layer 11 is lower than the dopant concentration in the first drain region 36 and lower than the concentration of an n type dopant in the source region 31.

The drain electrode 62 is formed on the drain region 35. The drain electrode 62 is electrically connected with the drain region 35. For example, the drain electrode 62 is brought into Ohmic contact with the drain region 35.

The gate insulation film 51 is formed on a region (a channel region, for example) between the source region 31 and the drain region 35. Silicon oxide or silicon oxynitride is used for forming the gate insulation film 51, for example. The gate electrode 63 is formed on the gate insulation film 51. Polysilicon is used for forming the gate electrode 63, for example.

The insulating separation film 52 is provided between the source region 31 and the drain region 36. The insulating separation film 52 is brought into contact with the drain region 35. The insulating separation film 52 has a Shallow Trench Isolation (STI) structure or a Local Oxidation of Silicon (LOCOS) structure, for example. Silicon oxide is used for forming the insulating separation film 52, for example. The insulating separation film 52 is formed on the front surface portion of the first semiconductor layer 12, for example.

The third semiconductor region 23 is provided between the first semiconductor region 21 and the drain region 35. A conductive type of the third semiconductor region is an n type. The third semiconductor region 23 is formed so as to be brought into contact with a lower surface (a surface which faces the first semiconductor layer 11 in an opposed manner) and a side surface (a surface which intersects with the second direction) of the insulating separation film 52, for example. The third semiconductor region 23 forms a drift layer, for example. A concentration of an n type dopant in the third semiconductor region 23 is higher than the concentration of an n type dopant in the second semiconductor layer 12 and lower than the concentration of an n type dopant in the second drain region 37, for example.

The interlayer insulation layer 53 is provided between the source electrode 61 and the drain electrode 62 and the gate electrode 63, for example.

In this embodiment, the second semiconductor region 22 is provided between the drain region 35 and the first semiconductor layer 11. A conductive type of the second semiconductor region 22 is a p type. For example, the second semiconductor region 22 may be brought into contact with the first semiconductor layer 11.

The concentration of a p type dopant in the second semiconductor region 22 is set to a relatively low value. For example, the concentration of a p type dopant in the second semiconductor region 22 is substantially equal to the concentration of an n type dopant in the second semiconductor layer 12.

A high voltage is usually applied to the drain electrode 62 (between the drain electrode 62 and the source electrode 61). For example, there may be a case where a voltage of approximately 10 V to 100 V is applied to the drain electrode 62. Due to the application of the high voltage, a strong electric field is generated around the drain region 35. There may be the case where an electric field reaches a critical field level such that an avalanche breakdown occurs. When the avalanche breakdown occurs, an electric current suddenly starts to flow between a source and a drain. A value of voltage corresponding to such a critical electric field is evaluated as the breakdown voltage of the semiconductor device.

Additionally, when a voltage is applied to the drain electrode 62, a depletion layer spreads in a pn junction between the second semiconductor region 22 and the second drain region 37, in pn junctions between the second semiconductor region 22 and the second semiconductor layers 12, and in a pn junction between the second semiconductor region 22 and the first semiconductor layer 11. For example, a dopant concentration in the second semiconductor region 22 is low so that the depletion layer spreads in the second semiconductor region 22. Due to the spreading of the depletion layer, an electric field around the drain region 35 is alleviated.

In this manner, in this embodiment, a p type semiconductor region (second semiconductor region 22) is formed below the drain region 35. Due to such a configuration, the depletion around the drain region 35 is promoted. An electric field generated by a voltage applied to the drain electrode is alleviated so that the breakdown voltage of the semiconductor device may be enhanced.

When the concentration of a p type dopant in the second semiconductor region 22 is high, there may be a case where a depletion layer does not sufficiently spread so that the breakdown voltage is not enhanced. For this reason, the concentration of a p type dopant in the second semiconductor region 22 is set approximately equal to the concentration of an n type dopant in the second semiconductor layer 12.

When both the concentration of a p type dopant and the concentration of an n type dopant are high in a pn junction boundary between the second semiconductor region 22 and the drain region 35, there may be a case where a strong electric field is generated to the contrary. In the same manner, when both the concentration of a p type dopant and the concentration of an n type dopant are high in a pn junction boundary between the second semiconductor region 22 and the first semiconductor layer 11, there may be a case where a strong electric field is generated. Due to the generation of such a strong electric field, there may be a case where the breakdown voltage lowered.

Accordingly, it is preferable that the concentration of a p type dopant in the second semiconductor region 22 is set to a low value in a boundary region between the second semiconductor region 22 and the second drain region 37 and in a boundary region between the second semiconductor region 22 and the first semiconductor layer 11. Accordingly, the semiconductor device 100 has a maximum value of a distribution (first distribution) of a concentration of a p type dopant in the second semiconductor region 22 along the Z axis direction between a boundary position between the second semiconductor region 22 and the second drain region 37 and a boundary position between the second semiconductor region 22 and the first semiconductor layer 11. Due to such a dopant concentration, it is possible to prevent a concentration of a p type dopant from becoming excessively high in the pn junction boundary thus suppressing the generation of a strong electric field.

The first distribution may have a plurality of maximum values at the boundary position between the second semiconductor region 22 and the second drain region 37 and at the boundary position between the second semiconductor region 22 and the first semiconductor layer 11.

For example, it is preferable that the maximum value of the first distribution be set in the vicinity of the center of the second semiconductor region 22 along the Z axis direction.

For example, when the first distribution has one maximum value, it is preferable that a distance in the Z axis direction between a boundary position between the second drain region 37 and the second semiconductor region 22 and a position of the maximum value of the first distribution is set to a value 0.2 or more times and 0.8 or less times as large as a length of the second semiconductor region 22 along the Z axis direction.

On the other hand, for example, when the first distribution has a plurality of maximum values, it is preferable that a distance in the Z axis direction between a boundary position between the second drain region 37 and the second semiconductor region 22 and a position of the maximum value of the first distribution be set to a value 0.1 times or more and 0.9 times or less as large as a length of the second semiconductor region 22 along the Z axis direction.

For example, as a method for enhancing the breakdown voltage, there has been known a semiconductor device of a reference example where a distance between a source region and a drain region is set large. In the semiconductor device having such a configuration, although the breakdown voltage is enhanced, a resistance in a region between the source region and the drain region also becomes large. That is, in a state where a voltage is applied to the gate electrode 63 so that an electric current (ON current) flows between the source electrode 61 and the drain electrode 62 (ON state), the electric resistance (ON resistance) between the source electrode 61 and the drain electrode 62 becomes high. In this manner, there exists the trade-off relationship between the enhancement of the breakdown voltage by changing a size of the device and the ON resistance.

For example, there has been known a semiconductor device having the n type DMOS structure of the reference example where semiconductor regions for forming a drain region and a source region are formed of p type semiconductor regions. That is, a p type semiconductor region is formed below a drift layer in the semiconductor device of the reference example. Also in the semiconductor device of the reference example having such a configuration, a depletion layer spreads around the drain region when a voltage is applied to the drain electrode. By adjusting a dopant concentration in the p type semiconductor region, an electric field may be alleviated thus enhancing the breakdown voltage.

In the semiconductor device of the reference example having such a configuration, however, the p type semiconductor region is formed in the vicinity of a path along which the ON current flows. Accordingly, there may be a case where an electric resistance (ON resistance) between the source electrode and the drain electrode becomes high when the semiconductor device is in the ON state. For example, there may be a case where a resistance in a diffusion layer becomes high due to the formation of the p type semiconductor region. In this manner, for example, there exists the trade-off relationship where when the breakdown voltage is enhanced by promoting the depletion, the ON resistance is increased (deteriorated).

On the other hand, in this embodiment, for example, the p type second semiconductor region 22 is formed on a portion between the drain region 35 and the first semiconductor layer 11. In this embodiment, the p type semiconductor region is not provided between the third semiconductor region 23 and the first semiconductor layer 11. In this manner, for example, a portion where the p type semiconductor region is formed is reduced near a path through which an ON current flows. Due to such a configuration, the deterioration of the ON resistance is reduced. In this manner, in this embodiment, the breakdown voltage may be enhanced by promoting the depletion around the drain region 35 while reducing the deterioration of the ON resistance.

For example, by adjusting a position where the second semiconductor region 22 is formed, it is possible to largely enhance the breakdown voltage while reducing the deterioration of the ON resistance.

For example, a first distance L1 between the first semiconductor region 21 and the drain region 35 along the second direction (the X axis direction in this embodiment) is smaller than a second distance L2 between the first semiconductor region 21 and the second semiconductor region 22 along the second direction. For example, a ratio of a fourth distance L4 between the second semiconductor region 22 and a center 35c of the drain region 35 along the second direction to a third distance L3 between the first semiconductor region 21 and the center 35c along the second direction is 0.5 or less. Due to such setting, the breakdown voltage is enhanced while reducing the deterioration of the ON resistance. In the embodiment, a position of the center 35c of the drain region 35 may be obtained based on a center point of the first drain region 36 interposed by the insulating separation films 52. That is, the position of the center 35c of the drain region 35 is an intermediate point between the insulating separation films 52 which sandwich the first drain region 35 therebetween.

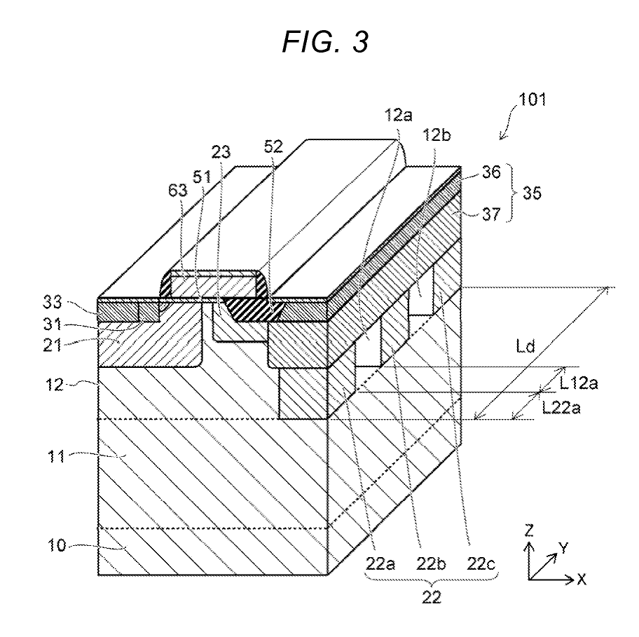

FIG. 3 is a schematic perspective view which exemplifies a semiconductor device 101 having the n type DMOS structure according to the modification of the first embodiment.

Also, in the semiconductor device 101, a first semiconductor layer 11, a second semiconductor layer 12, a first semiconductor region 21, a second semiconductor region 22, a source region 31, a drain region 35 and the like are formed.

The second semiconductor region 22 of the semiconductor device 101 includes a first portion 22a, a second portion 22b, and a third portion 22c.

The second portion 22b is separated from the first portion 22a in the third direction (the Y axis direction, for example). In this embodiment, the third portion 22c is separated from the first portion 22a and the second portion 22b in the third direction. The third direction is the direction which intersects with the first direction (Z axis direction) and intersects with the second direction (the X axis direction, for example).

A similar explanation regarding the second semiconductor region 22 of the semiconductor device 100 is applicable to the first to third portions 22a to 22c. That is, a conductive type of the first to third portions 22a to 22c is a p type. A concentration of a p type dopant in each of the first to third portions 22a to 22c is set to a relatively low value in the same manner as the second semiconductor region 22.

An n type semiconductor region 12a is provided between the first portion 22a and the second portion 22b. An n type semiconductor region 12b is provided between the second portion 22b and the third portion 22c. That is, the second semiconductor layer 12 includes the semiconductor region 12a and the semiconductor region 12b.

For example, a length L22a of the first portion 22a along the third direction is 0.3 or more times and 0.7 or less times as large as a distance Ld of the drain region 35 along the third direction. For example, a length L12a of the semiconductor region 12a along the third direction is 0.3 or more times and 0.7 or less times as large as the distance Ld of the drain region 35 in the third direction.

For example, a ratio of the length L22a of the first portion 22a in the third direction to the length L12a of the semiconductor region 12a in the third direction is 0.5 or more and 2 or less.

The second semiconductor region 22 is divided in this manner in the semiconductor device 101. By dividing the second semiconductor region 22, the area of a pn junction arranged between the p type second semiconductor region 22 and the n type region arranged around the p type second semiconductor region 22 (the first semiconductor layer 11, the second semiconductor layer 12 and the drain region 35) is increased. Due to the increase of the area of the pn junction, a depletion layer is increased, for example. When a high voltage is applied to the drain electrode 62, the depletion is promoted around the drain region 35. Due to such depletion, the breakdown voltage of the semiconductor device may be enhanced.

Further, when the second semiconductor region 22 is divided, the p type semiconductor region formed around the drain region 35 (in a path along which an ON current flows) is made small, as compared to a case where the second semiconductor region 22 is not divided. Due to such a configuration, for example, the deterioration of an ON resistance may be reduced. The breakdown voltage with respect to an ON resistance may be further enhanced.

### SECOND EMBODIMENT

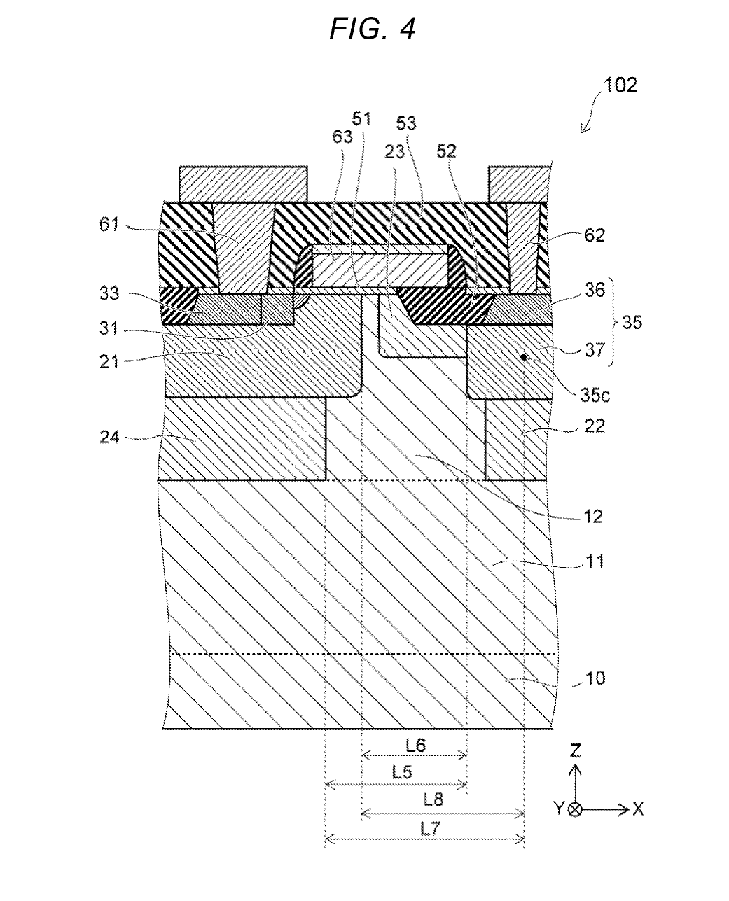

FIG. 4 is a schematic cross-sectional view which exemplifies a semiconductor device according to the second embodiment.

FIG. 4 exemplifies a semiconductor device 102 having the n type DMOS structure. Also in the semiconductor device 102, a first semiconductor layer 11, a second semiconductor layer 12, a first semiconductor region 21, a source region 31, a drain region 35 and the like are formed. Configurations substantially identical with the configuration explained with respect to the semiconductor device 100 are given the same symbols, and the repeated explanation is omitted.

As illustrated in FIG. 4, the semiconductor device 102 further includes a p type fourth semiconductor region 24. The fourth semiconductor region 24 is provided between the first semiconductor region 21 and the first semiconductor layer 11.

The fourth semiconductor region 24 may be brought into contact with the first semiconductor layer 11, for example. The fourth semiconductor region 24 may be brought into contact with the first semiconductor region 21, for example.

A pn junction is formed at a boundary between the fourth semiconductor region 24 and the first semiconductor layer 11. By adjusting a position of the fourth semiconductor region 24 or a dopant concentration in the fourth semiconductor region 24, an electric field generated between the fourth semiconductor region 24 and the first semiconductor layer 11 may be strengthened, for example. By strengthening the electric field between the fourth semiconductor region 24 and the first semiconductor layer 11, an electric field around the drain region 35 may be alleviated. In this manner, by forming the p type semiconductor region between the first semiconductor layer 11 and the first semiconductor region 21, the breakdown voltage is further improved.

For example, it is preferable that a concentration of a p type dopant in the fourth semiconductor region 24 is lower than a concentration of a p type dopant in the first semiconductor region 21. By setting the concentration of a p type dopant in this manner, an electric field generated between the fourth semiconductor region 24 and the first semiconductor layer 11 is strengthened.

When a p type semiconductor region like the fourth semiconductor region 24 is formed at a position close to a path through which an ON current flows, an electric resistance in the path through which the ON current flows is increased. Accordingly, it is preferable that a portion where the fourth semiconductor region 24 is formed is not excessively large.

Thus, it is preferable that a fifth distance L5 between the fourth semiconductor region 24 and the drain region 35 along the second direction is larger than a sixth distance L6 between the first semiconductor region 21 and the drain region 35 along the second direction.

Additionally, it is preferable that a seventh distance L7 between the center 35c of the drain region 35 and the fourth semiconductor region 24 along the second direction is larger than an eighth distance L8 between the center 35c and the first semiconductor region 21 along second direction.

When a fourth semiconductor region 24 having such a configuration is formed, the breakdown voltage may be enhanced while reducing the deterioration of the ON resistance. In the embodiment, both the second semiconductor region 22 and the fourth semiconductor region 24 may be formed. By forming both the second semiconductor region 22 and the fourth semiconductor region 24, the breakdown voltage with respect to an ON resistance may be further enhanced. In such a case, the fourth semiconductor region 24 may be diffused in the same manner as the second semiconductor region 22. That is, the distribution of concentration of a p type dopant in the fourth semiconductor layer 24 in the Z axis direction may be set substantially equal to the distribution of concentration of a p type dopant in the second semiconductor region 22 in the Z axis direction.

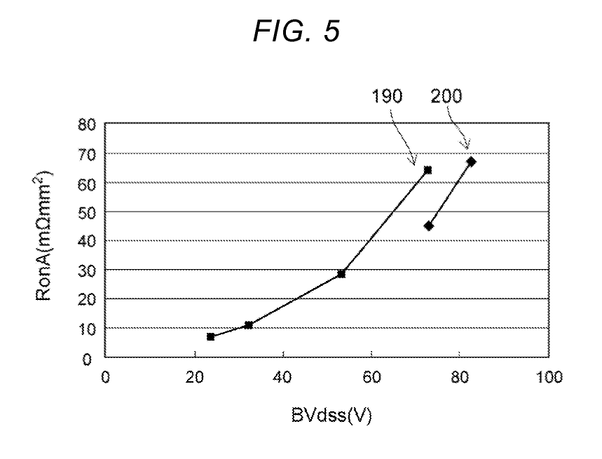

FIG. 5 is a graph which exemplifies a characteristic of the semiconductor device.

A solid line 200 exemplifies the relationship between the breakdown voltage and an ON resistance of the semiconductor device 100 according to the embodiment, while a solid line 190 exemplifies the relationship between the breakdown voltage and an ON resistance of the semiconductor device according to the reference example.

An ON resistance RonA (mΩmm²) is taken on an axis of ordinates in FIG. 5. The breakdown voltage BVdss (V) is taken on an axis of abscissas in FIG. 5. The second semiconductor region 22 is not formed in the semiconductor device of the reference example. Except that the second semiconductor region 22 is not formed, configurations of the semiconductor device of the reference example are substantially equal to the corresponding configurations of the semiconductor device 100 which are explained above.

The graph depicted in FIG. 5 is a result calculated by a simulation. A gate length (a length of the gate electrode 63 along the X axis direction) is 2.7 μm in the simulation. A depth of the drain region 35 (a length along the Z axis direction) is 1.7 μm. A ratio of the fourth distance L4 to the third distance L3 is approximately 0.3. The breakdown voltage BVdss is a drain voltage at which the gate electrode 63 and the source electrode 61 are short circuited, and a drain current exceeding a predetermined threshold voltage flows when a voltage is applied to the drain electrode 62.

As illustrated in FIG. 5, in the semiconductor device 100 and the semiconductor device according to the reference example, the higher the breakdown voltage BVdss is, the higher the ON resistance RonA becomes. In the semiconductor device according to the reference example, when the ON resistance RonA is 50 mΩmm², the breakdown voltage is approximately 64 V. On the other hand, in the semiconductor device 100, when the ON resistance RonA is 50 mΩmm², the breakdown voltage is approximately 75 V. In this manner, the breakdown voltage BVdss with respect to the ON resistance RonA may be enhanced.

According to the embodiment, it is possible to provide the semiconductor device where the breakdown voltage is enhanced while suppressing the increase of the ON resistance.

In the disclosure, “perpendicular” means not only “perpendicular” in a strict meaning of the term but also “approximately perpendicular having a variation which is caused in a manufacturing step or the like”, for example. That is, “perpendicular” also encompasses “substantially perpendicular.”

The embodiments of the present disclosure have been explained by reference to the specific examples heretofore. However, the embodiments of the present disclosure are not limited to these specific examples. For example, with respect to the specific configurations of the respective elements such as the first semiconductor layer, the second semiconductor layer, the first to fourth semiconductor regions, the source region, the drain region, the gate insulation film, the gate electrode, the source electrode, the drain electrode, or the insulating separation film, these configurations fall within the scope of the present disclosure provided that those who are skilled in the art may carry out the present exemplary embodiments in the same manner as these embodiments by suitably selecting the configurations from a known range and may acquire the substantially equal advantageous effects as these embodiments.

Further, the combination of two or more elements in each specific example within a technically possible range also falls within the scope of the present disclosure provided that the combination contains the gist of the present disclosure.

Further, all semiconductor devices which those who are skilled in the art may carry out by suitably changing designs based on the semiconductor devices described above as the embodiments of the present disclosure also fall within the scope of the present exemplary embodiments so long as these semiconductor devices contain the gist of the present disclosure.

Still further, various variations and modifications are conceivable to those who are skilled in the art within a category of the technical concept of the present disclosure, and it is construed that these variations and modifications also fall within the scope of the present exemplary embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer of a first conductive type;
a second semiconductor layer of the first conductive type on the first semiconductor layer, and having a dopant concentration lower than a dopant concentration of the first semiconductor layer;
a first semiconductor region of a second conductive type in the second semiconductor layer;
a source region of the first conductive type in the first semiconductor region;
a drain region of the first conductive type in the second semiconductor layer, and spaced from the source region in a first direction that is parallel to a surface of the second semiconductor layer;
a second semiconductor region of the second conductive type in the second semiconductor layer and between the drain region and the first semiconductor layer; and
a gate electrode on the surface of the second semiconductor layer between the drain region and the source region.

2. The semiconductor device according to claim 1, wherein the second semiconductor region is in direct contact with the first semiconductor layer.

3. The semiconductor device according to claim 1 , wherein a ratio between one-half of a width, along the first direction, of the second semiconductor region and a distance, along the first direction, from a center, with respect to the first direction, of the drain region to the first semiconductor region is 0.5 or less.

4. The semiconductor device according to claim 1, wherein a concentration distribution of a dopant of the second conductive type within the second semiconductor region and along a second direction orthogonal to the surface of the second semiconductor layer has a maximum value between the drain region and the first semiconductor layer.

5. The semiconductor device according to claim 4, wherein the concentration distribution of the dopant of the second conductivity type within the second semiconductor region has a plurality of local maximum values.

6. The semiconductor device according to claim 1, wherein a concentration of dopant of the first conductive type in the drain region is higher than a concentration of dopant of the second conductive type in the second semiconductor region.

7. The semiconductor device according to claim 1, wherein the second semiconductor region includes a first portion and a second portion spaced from the first portion, in a gate width direction that is parallel to the surface of the second semiconductor layer and perpendicular to the first direction.

8. The semiconductor device according to claim 7, wherein the second semiconductor layer is between the first portion and the second portion.

9. The semiconductor device according to claim 1, further comprising:
an insulation film between the source region and the drain region, and directly contacting the drain region.

10. The semiconductor device according to claim 1, further comprising:
a third semiconductor region of the first conductive type between the first semiconductor region and the drain region, and directly contacting the drain region, wherein a concentration of dopant of the first conductive type in the third semiconductor region is lower than a concentration of dopant of the first conductive type in the drain region.

11. The semiconductor device according to claim 1, further comprising:
a fourth semiconductor region of the second conductive type between the first semiconductor region and the first semiconductor layer.

12. A semiconductor device, comprising:
a first semiconductor layer of a first conductive type;
a second semiconductor layer of the first conductive type on the first semiconductor layer, and having a dopant concentration lower than a dopant concentration of the first semiconductor layer;
a first semiconductor region of a second conductive type in the second semiconductor layer;
a source region of the first conductive type in the first semiconductor region;
a drain region of the first conductive type in the second semiconductor layer, and spaced from the source region in a first direction that is parallel to a surface of the second semiconductor layer;
a fourth semiconductor region of the second conductive type in the second semiconductor layer and between the first semiconductor region and the first semiconductor layer; and
a gate electrode on the surface of the second semiconductor layer between the drain region and the source region.

13. The semiconductor device according to claim 12, wherein a distance along the first direction from the fourth semiconductor region to a center, with respect to the first direction, of the drain region is greater than a distance along the first direction from the first semiconductor region to the center of the drain region.

14. The semiconductor device according to claim 12, wherein a concentration of dopant of the second conductive type in the fourth semiconductor region is lower than a concentration of dopant of the second conductive type in the first semiconductor region.

15. The semiconductor device according to claim 12, further comprising:
a second semiconductor region of the second conductive type in the second semiconductor layer and between the drain region and the first semiconductor layer.

16. The semiconductor device according to claim 15, wherein the second semiconductor region includes a first portion and a second portion spaced from the first portion, in a gate width direction that is parallel to the surface of the second semiconductor layer and perpendicular to the first direction.

17. A semiconductor device, comprising:
a semiconductor layer having a first portion and a second portion, the first portion having a concentration of a first conductivity type dopant that is greater than a concentration of the first conductivity type dopant in the second portion, the second portion being between the first portion and a surface of the semiconductor layer;
a source and drain region in the second portion of the semiconductor layer and spaced from each other in a first direction parallel to the surface of the semiconductor layer, the drain region having a first part at the surface of the semiconductor layer and a second part between the first portion of the semiconductor layer and the first part, the first part having a concentration of the first conductivity type dopant that is greater than a concentration of the first conductivity type dopant in the second part;
a gate electrode on the surface of the semiconductor layer between the source and drain regions; and
a semiconductor region in the second portion of semiconductor layer between the second part of the drain region and the first portion of the semiconductor layer and having a second conductivity type that is opposite the first conductivity type, the semiconductor region being in direct contact with the second part of the drain region, the second portion of the semiconductor layer, and the first portion of the semiconductor layer.

18. The semiconductor device according to claim 17, wherein the semiconductor region is provided as a plurality portions spaced from each other in a second direction perpendicular to the first direction and parallel to the surface of the semiconductor layer.

19. The semiconductor device according to claim 17, further comprising:
a second semiconductor region of the second conductivity type in the second portion of semiconductor layer and between the source region and the first portion of the semiconductor layer, the second semiconductor region being in direct contact with the second portion of the semiconductor layer and the first portion of the semiconductor layer.

20. The semiconductor device according to claim 17, wherein the semiconductor layer has a gradient in concentration of first conductivity type dopant along a direction orthogonal to the surface of the semiconductor layer, and the gradient has a maximum value in the first portion of the semiconductor layer.
